(19) United States
(12) Patent Application Publication
(10) Pub. No.: US 2024/0186231 A1
(43) Pub. Date: Jun. 6, 2024

(54) SEMICONDUCTOR PACKAGE INCLUDING A REDISTRIBUTION STRUCTURE

(71) Applicant: SAMSUNG ELECTRONICS CO., LTD., Suwon-si (KR)

(72) Inventors: Jihwang KIM, Suwon-si (KR); Joonsung KIM, Suwon-si (KR); Sangjin Baek, Suwon-si (KR); Kyounglim Suk, Suwon-si (KR)

(21) Appl. No.: 18/520,453

(22) Filed: Nov. 27, 2023

(30) Foreign Application Priority Data
Dec. 2, 2022 (KR) 10-2022-0167036

(51) Int. Cl. H01L 23/498; H01L 23/00; H01L 23/31; H01L 23/522; H01L 25/065

(52) U.S. Cl. CPC H01L 23/49822; H01L 23/3128; H01L 23/49816; H01L 23/49838; H01L 23/5226; H01L 24/08; H01L 24/16; H01L 24/32; H01L 24/73; H01L 25/0657; H01L 2224/08235; H01L 2224/16227; H01L 2224/32225; H01L 2224/73204; H01L 2225/06544; H01L 2924/1431; H01L 2924/1436; H01L 2924/1437; H01L 2924/1438; H01L 2924/1441; H01L 2924/181

(57) ABSTRACT

A semiconductor package includes a lower redistribution structure. A semiconductor device is disposed on the lower redistribution structure. A lower encapsulant is disposed on the lower redistribution structure and surrounds a side surface of the semiconductor device. An upper composite redistribution structure is disposed on an upper portion of the semiconductor device and includes a primary conductive structure, a secondary conductive structure disposed on the primary conductive structure, connection vias disposed between the primary conductive structure and the secondary conductive structure, and an upper encapsulant disposed between the primary conductive structure and the secondary conductive structure and surrounding the connection vias.

### CROSS-REFERENCE TO RELATED APPLICATIONS

The present application claims priority under 35 U.S.C. § 119 to Korean Patent Application No. 10-2022-0167036, filed on Dec. 2, 2022, in the Korean Intellectual Property Office, the disclosure of which is incorporated by reference herein in its entirety.

### TECHNICAL FIELD

The present disclosure relates to a semiconductor package, and more particularly, to a semiconductor package including a redistribution structure.

### DISCUSSION OF THE RELATED ART

In accordance with the rapid development of the electronics industry and the demands of users, electronic devices are becoming more compact, multifunctional, and large-capacity, and accordingly, highly integrated semiconductor chips are being used. Therefore, for highly integrated semiconductor chips with an increased number of connection terminals for input/output (I/O), a semiconductor package having connection terminals with reliable connections is being designed. One example of such a structure is a fan-out semiconductor package that has increased spacing between connection terminals so as to reduce interference between the connection terminals.

### SUMMARY

A semiconductor package includes a lower redistribution structure. A semiconductor device is disposed on the lower redistribution structure. A lower encapsulant is disposed on the lower redistribution structure and surrounds a side surface of the semiconductor device. An upper composite redistribution structure is disposed on an upper portion of the semiconductor device and includes a primary conductive structure, a secondary conductive structure disposed on the primary conductive structure, connection vias disposed between the primary conductive structure and the secondary conductive structure, and an upper encapsulant disposed between the primary conductive structure and the secondary conductive structure and surrounding the connection vias.

A semiconductor package includes a lower redistribution structure. A semiconductor device is disposed on the lower redistribution structure. A lower encapsulant is disposed on the lower redistribution structure and surrounds a side surface of the semiconductor device on the lower redistribution structure. An upper composite redistribution structure is disposed on an upper portion of the semiconductor device and includes a first conductive structure, a second conductive structure disposed on an upper portion of the first conductive structure, connection vias disposed between the first conductive structure and the second conductive structure, an upper encapsulant disposed between the primary conductive structure and the secondary conductive structure and surrounding side surfaces of the connection vias, and a connection pad electrically connected with each of the connection vias and disposed on the second conductive structure. Conductive posts electrically connect the upper composite redistribution structure with the lower redistribution structure and are spaced apart from the semiconductor device.

A semiconductor device includes a lower redistribution structure. A semiconductor device is disposed on the lower redistribution structure and includes a logic device. A lower encapsulant is disposed on the lower redistribution structure and surrounds a side surface of the semiconductor device. An upper composite redistribution structure is disposed on the semiconductor device. Conductive posts electrically connect the upper composite redistribution structure with the lower redistribution structure and are spaced apart from the semiconductor device. An upper semiconductor device is mounted on the upper composite redistribution structure and includes a memory device. The upper composite redistribution structure includes a primary conductive structure, a secondary conductive structure disposed on an upper portion of the primary conductive structure, connection vias disposed between the primary conductive structure and the secondary conductive structure, a heat dissipation plate disposed between the primary conductive structure and the secondary conductive structure and laterally spaced apart from the connection vias, an upper encapsulant disposed between the primary conductive structure and the secondary conductive structure and surrounding the connection vias and a side surface of the heat dissipation plate, first heat dissipation vias passing through the primary conductive structure, and having one end contacting a top surface of the semiconductor device and the other end contacting the heat dissipation plate, second heat dissipation vias passing through the secondary conductive structure and having one end contacting the heat dissipation plate, a connection pad electrically connected to each of the connection vias and arranged on the secondary conductive structure, and a heat dissipation pad arranged on the secondary conductive structure and having a bottom surface contacting the other end of each of the second heat dissipation vias.

### BRIEF DESCRIPTION OF THE DRAWINGS

Embodiments of the inventive concept will be more clearly understood from the following detailed description taken in conjunction with the accompanying drawings in which:

FIG. 1 is a cross-sectional view illustrating a semiconductor package, according to an embodiment of the present disclosure;

FIG. 2A is a plan view taken along a portion A-A′ of the semiconductor package of FIG. 1, according to an embodiment of the present disclosure;

FIG. 2B is a plan view taken along the portion A-A′ of the semiconductor package of FIG. 2A, according to an embodiment of the present disclosure;

FIG. 3 is a cross-sectional view illustrating a semiconductor package, according to an embodiment of the present disclosure;

FIG. 4 is a cross-sectional view illustrating a semiconductor package, according to an embodiment of the present disclosure;

FIG. 5A is a plan view taken along the portion A-A′ of the semiconductor package of FIG. 1, according to an embodiment of the present disclosure;

FIG. 5B is a plan view taken along the portion A-A′ of the semiconductor package of FIG. 1, according to an embodiment of the present disclosure;

FIG. 6 is a cross-sectional view illustrating a semiconductor package, according to an embodiment of the present disclosure;

FIG. 7 is a cross-sectional view illustrating a semiconductor package, according to an embodiment of the present disclosure;

FIG. 8 is a cross-sectional view illustrating a semiconductor package, according to an embodiment of the present disclosure;

FIG. 9 is a plan view taken along a portion A-A′ of the semiconductor package of FIG. 8, according to an embodiment of the present disclosure;

FIG. 10 is a cross-sectional view illustrating a semiconductor package, according to an embodiment of the present disclosure;

FIG. 11 is a plan view taken along a portion A-A′ of the semiconductor package of FIG. 10, according to an embodiment;

FIG. 12 is a cross-sectional view illustrating a semiconductor package according to an embodiment of the present disclosure;

FIG. 13 is a plan view taken along a portion A-A′ of the semiconductor package of FIG. 12, according to an embodiment of the present disclosure; and

FIGS. 14A to 14E are cross-sectional views sequentially showing a process of manufacturing a semiconductor package, according to an embodiment of the present disclosure.

### DETAILED DESCRIPTION OF THE EMBODIMENTS

Hereinafter, embodiments of the technical idea of the inventive concept will be described in detail with reference to the accompanying drawings. The same reference numerals may be used for the same components in the drawings, and to the extent that an element is not described in detail herein, it may be assumed that the element is at least similar to a corresponding element that has been described in detail elsewhere within the present disclosure.

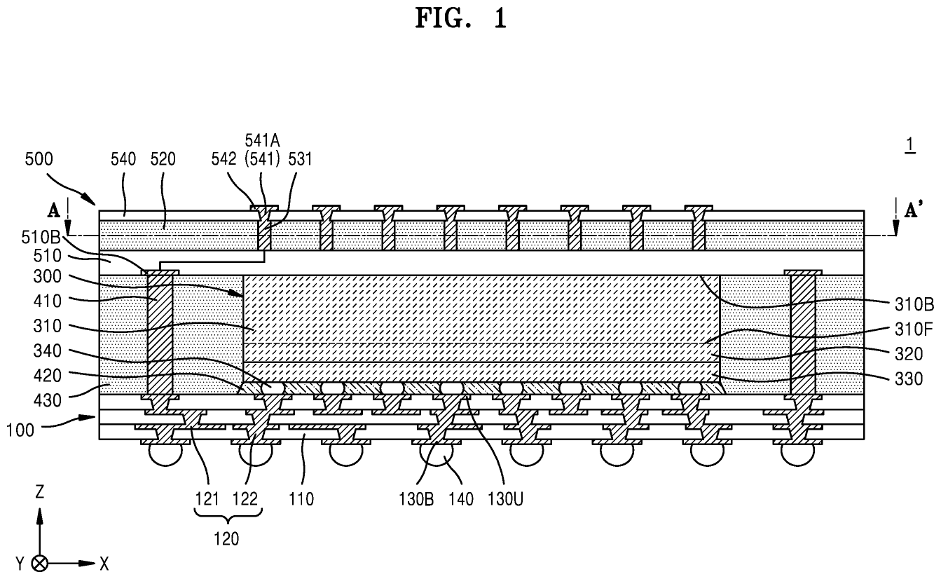

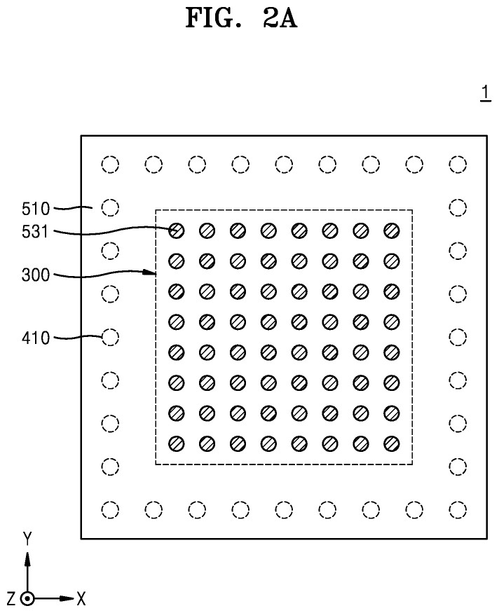

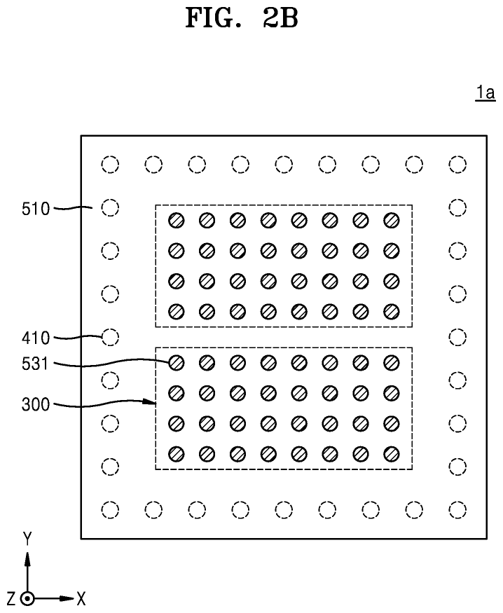

FIG. 1 is a cross-sectional view illustrating a semiconductor package 1, according to an embodiment of the present disclosure. FIG. 2A is a plan view taken along a portion A-A′ of the semiconductor package 1 of FIG. 1, according to an embodiment of the present disclosure. FIG. 2B is a plan view taken along the portion A-A′ of the semiconductor package 1 of FIG. 2A, according to an embodiment of the present disclosure. Hereinafter, the plane referred to in the present specification is an X-Y plane.

Referring to FIGS. 1, 2A, and 2B, the semiconductor package 1 may include a lower redistribution structure 100, an internal semiconductor device 300 mounted on the lower redistribution structure 100, conductive posts 410 spaced apart from the internal semiconductor device 300, and an upper composite cultivation structure 500 disposed above the internal semiconductor device 300.

The semiconductor package 1 may be a fan out semiconductor package in which the width and area of the lower redistribution structure 100 in the horizontal direction are larger than the width and area horizontally configured by the internal semiconductor device 300. In some embodiments, the semiconductor package 1 may be a Fan Out Wafer Level Package (FOWLP) or a Fan Out Panel Level Package (FOPLP).

In some embodiments, the lower redistribution structure 100 may be formed by a redistribution process.

The lower redistribution structure 100 may include a redistribution insulation layer 110 and a plurality of redistribution patterns 120. The redistribution insulation layer 110 may at least partially surround the plurality of redistribution patterns 120. In some embodiments, the lower redistribution structure 100 may include a plurality of stacked redistribution insulation layers 110. The redistribution insulation layer 110 may include, for example, a photo imageable dielectric (PID) or a photosensitive polyimide (PSPI).

The plurality of redistribution patterns 120 may include a plurality of redistribution line patterns 121 and a plurality of redistribution via patterns 122. The plurality of redistribution patterns 120 may be, for example, a metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru) or the like, or a metal alloy thereof, but the present invention is not necessarily limited thereto.

The plurality of redistribution line patterns 121 may be arranged on a top surface and/or a bottom surface of the redistribution insulation layer 110. For example, when the lower redistribution structure 100 includes a plurality of stacked redistribution insulation layers 110, the redistribution line patterns 121 may be arranged on the top surface of the uppermost redistribution insulation layer 110 and the bottom surface of the lowermost redistribution insulation layer 110, and between the neighboring redistribution insulation layers 110.

The plurality of redistribution via patterns 122 may be connected to some of the plurality of redistribution line patterns 121 through the redistribution insulation layer 110. In some embodiments, the plurality of redistribution via patterns 122 may have tapered shapes in which the horizontal widths increase and extend from the bottom to the top of each of the redistribution vias.

In some embodiments, some of the plurality of redistribution line patterns 121 may be formed together with some of the plurality of redistribution via patterns 122 to form a single integral structure. For example, each of the redistribution line patterns 121 and each of the redistribution via patterns 122 in contact with the bottom surface of each of the redistribution line patterns 121 may be formed together as a single integral structure.

Among the plurality of redistribution patterns 120, some arranged adjacent to the bottom surface of the lower redistribution structure 100 may be referred to as a plurality of lower surface connection pads 130B, and some arranged adjacent to the top surface of the lower redistribution structure 100 may be referred to as a plurality of top surface connection pads 130U. For example, the plurality of bottom surface connection pads 130B may be some of the plurality of redistribution line patterns 121 arranged adjacent to the bottom surface of the lower redistribution structure 100, and the plurality of top surface connection pads 130U may be some of the plurality of redistribution line patterns 121 arranged adjacent to the upper surface of the lower redistribution structure 100.

A plurality of external connection terminals 140 may be attached to the plurality of bottom surface connection pads 130B. The plurality of external connection terminals 140 may externally connect the semiconductor package 1. In some configurations, the plurality of external connection terminals 140 may be solder bumps or solder balls. Alternatively, a plurality of chip connection members 340 (e.g., chip connectors) may be attached to some of the plurality of top surface connection pads 130U, and a plurality of conductive posts 410 may be attached to the others thereof.

The plurality of top surface connection pads 130U may be arranged on the top surface of the redistribution insulation layer 110. For example, when the lower redistribution structure 100 includes the plurality of stacked redistribution insulation layers 110, the plurality of top surface connection pads 130U may be arranged on the top surface of the uppermost redistribution insulation layer 110.

At least one internal semiconductor device 300 may be mounted on the lower redistribution structure 100. For example, the internal semiconductor device 300 may include a single internal semiconductor device or a plurality of internal semiconductor devices. The internal semiconductor device 300 may include a semiconductor substrate 310 having an active surface 310F and an inactive surface 310B facing each other, a FEOL layer 320 formed on the active surface 310F of the semiconductor substrate 310, a BEOL layer 330 provided under the FEOL layer 320, and a plurality of chip pads arranged on a first surface of the internal semiconductor device 300. For example, the internal semiconductor device 300 may have a thickness of about 150 μm or more in a vertical direction.

Here, the first and second surfaces of the internal semiconductor device 300 face each other, and the second surface of the internal semiconductor device 300 means the inactive surface 310B of the semiconductor substrate 310. The active surface 310F of the semiconductor substrate 310 may be adjacent to the first surface of the internal semiconductor device 300. Accordingly, the FEOL layer 320 and the BEOL layer 330 corresponding to the semiconductor device layer may be illustrated thicker than the actual semiconductor device 300.

In some embodiments, the internal semiconductor device 300 has a face-down arrangement in which the first surface faces the lower redistribution structure 100, and may be mounted on the top surface of the lower redistribution structure 100. In this case, the first surface of the internal semiconductor device 300 may be referred to as a bottom surface of the internal semiconductor device 300, and the second surface of the internal semiconductor device 300 may be referred to as a top surface of the internal semiconductor device 300.

A plurality of chip connection members 340 may be located between a plurality of chip pads of the internal semiconductor device 300 and some of the plurality of top surface connection pads 130U of the lower redistribution structure 100. For example, each of the plurality of chip connection members 340 may be a solder ball or a micro bump. The internal semiconductor device 300 and the redistribution patterns 120 of the lower redistribution structure 100 may be electrically connected through the plurality of chip connection members 340. The plurality of chip connection members 340 may include an under bump metal (UBM) layer disposed on the plurality of chip pads and a conductive connection member covering the UBM layer. The plurality of chip connection members 340 may include, for example, copper (Cu), aluminum (Al), silver (Ag), tin (Tin), gold (Au), or solder, but are not necessarily limited thereto.

The semiconductor substrate 310 may include, for example, a semiconductor material such as silicon (Si) or germanium (Ge). Alternatively, the semiconductor substrate 310 may include a compound semiconductor material, such as silicon carbide (SiC), gallium arsenide (GaAs), indium arsenide (InAs), and indium phosphide (InP). The semiconductor substrate 310 may include a well doped with impurities as a conductive region. The semiconductor substrate 310 may have various device isolation structures such as a shallow trench isolation (STI) structure.

A semiconductor device including a plurality of types of individual devices may be formed on the active surface of the semiconductor substrate 310. The plurality of individual devices may be electrically connected to the conductive region of the semiconductor substrate 310. The semiconductor device may further include a conductive wiring or a conductive plug electrically connecting the plurality of individual devices with the conductive region of the semiconductor substrate 310. In addition, each of the plurality of individual devices may be electrically separated from other neighboring individual devices by an insulating film.

In some embodiments, the internal semiconductor device 300 may include a logic device. For example, the internal semiconductor device 300 may be a central processing device chip, a graphic processing device chip, or an application processor (AP) chip. In other embodiments, when the semiconductor package 1 includes the plurality of internal semiconductor devices 300, one of the plurality of internal semiconductor devices 300 may be a central processing unit chip, a graphic processing unit chip, or an application processor chip, and the other may be a memory semiconductor chip including a memory device.

For example, the memory device may be a nonvolatile memory device, such as flash memory, phase-change random access memory (PRAM), magnetoresistive random access memory (MRAM), ferroelectric random access memory (FeRAM), or resistive random access memory (RRAM). In some embodiments, the memory device may be a volatile memory device, such as dynamic random access memory (DRAM) or static random access memory (SRAM).

The internal semiconductor device 300 may be a semiconductor device in which a plurality of semiconductor chips are vertically stacked. The plurality of semiconductor chips may be stacked semiconductor chips including a Through Silicon Via (TSV).

The lower encapsulant 430 may at least partially surround the internal semiconductor device 300 and the conductive posts 410 on the top surface of the lower redistribution structure 100. The lower encapsulant 430 may fill a space between the lower redistribution structure 100 and the upper composite redistribution structure 500 to be described later. For example, the lower encapsulant 430 may have a thickness of about 150 μm to about 500 μm. For example, the lower encapsulant 430 may be a molding member (e.g., a molding) including an epoxy mold compound (EMC). The lower encapsulant 430 may further include a filler.

In some embodiments, an underfill layer 420 surrounding the plurality of chip connection members 340 may be located between the internal semiconductor device 300 and the lower redistribution structure 100. In some embodiments, the underfill layer 420 may fill a space between the internal semiconductor device 300 and the lower redistribution structure 100 and may cover a portion of a lower side of a side surface of the internal semiconductor device 300. The underfill layer 420 may be formed by, for example, a capillary underfill process, and may include an epoxy resin.

In some embodiments, the side surface of the lower redistribution structure 100, the side surface of the lower encapsulant 430, and the side surface of the upper composite redistribution structure 500 may be aligned vertically to form a coplanar surface.

A plurality of conductive posts 410 may electrically connect the lower redistribution structure 100 with the upper composite redistribution structure 500 through the lower encapsulant 430. The lower encapsulant 430 may at least partially surround the plurality of conductive posts 410.

The plurality of conductive posts 410 may be horizontally spaced apart from the internal semiconductor device 300 and may be located between the lower redistribution structure 100 and the upper composite redistribution structure 500. For example, the plurality of conductive posts 410 may be horizontally spaced apart from the internal semiconductor device 300, and may be arranged around the internal semiconductor device 300 in an outer region of the lower redistribution structure 100.

The plurality of conductive posts 410 may be located between a plurality of top surface connection pads 130U and a plurality of bottom surface connection pads 510B to be described later. The bottom surfaces of the plurality of conductive posts 410 may be in contact with the plurality of top surface connection pads 130U of the lower redistribution structure 100 to be electrically connected to the plurality of redistribution patterns 120, and the top surfaces of the plurality of conductive posts 410 may be in contact with the plurality of bottom surface connection pads 510B of the upper composite redistribution structure 500 to be electrically connected to a plurality of redistribution patterns.

For example, the length of each of the plurality of conductive posts 410 in the vertical direction may be about 200 μm to about 500 μm, and the width of each of the plurality of conductive posts 410 in the horizontal direction may be about 120 μm to about 200 μm. An aspect ratio of each of the plurality of conductive posts 200, for example, a ratio of a height to a horizontal width, may be greater than 1. In some embodiments, the plurality of conductive posts 410 may include copper (Cu) or a copper (Cu) alloy, but are not necessarily limited thereto.

A bottom surface of each of the plurality of conductive posts 410 may be in contact with each of the top surface connection pads 130U. A top surface of each of the plurality of conductive posts 410 may be in contact with each of the bottom surface connection pads 510B.

In some embodiments, the horizontal width and area of each of the top surface connection pads 130U in contact with each of the conductive posts 410 may be greater than the width and area of each of the conductive posts 410 in the horizontal direction. For example, the entire bottom surfaced of the conductive posts 410 may be in contact with the top surfaced of the top surface connection pads 130U, but some of the top surfaced of the top surface connection pads 130U might not be in contact with the plurality of conductive posts 410.

In some embodiments, the horizontal width and area of each of the bottom surface connection pads 510B in contact with each of the conductive posts 410 may be greater than the horizontal width and area of each of the conductive posts 410. For example, the entire top surfaces of the conductive posts 410 may be in contact with the bottom surfaces of the bottom surface connection pads 510B, but some of the bottom surfaces of the bottom surface connection pads 510B might not be in contact with the plurality of conductive posts 410.

The upper composite redistribution structure 500 may include: a primary conductive structure 510 positioned on an inactive surface 310B that is a top surface of the internal semiconductor device 300; a plurality of connection vias 531 having one end positioned on the primary conductive structure 510; a secondary conductive structure 540 positioned at the other end of the connection vias 531; an upper encapsulant 520 located between the primary conductive structure 510 and the secondary conductive structure 540 and surrounding the connection vias 531; and a plurality of secondary top surface connection pads 542 arranged on the secondary conductive structure 540 and electrically connected to the connection vias 531.

In some embodiments, the primary conductive structure 510 may be formed by the redistribution process described above. The primary conductive structure 510 may include a redistribution insulation layer and a plurality of redistribution patterns. The primary conductive structure 510 may include a plurality of redistribution insulation layers. The primary conductive structure 510 may include one or more layers of redistribution patterns. As shown in FIG. 1, the primary conductive structure 510 may include a redistribution structure connecting the bottom surface connection pads 510B with the connection vias 531. However, for the convenience of illustration, it will be understood by one of ordinary skill in the art that the specific redistribution structure of the primary conductive structure 510 is omitted from the drawing but is understood to be part of the embodiment of the present disclosure.

Like the lower redistribution structure, the plurality of redistribution patterns of the primary conductive structure 510 may include a plurality of redistribution line patterns and a plurality of redistribution via patterns. To the extent that an element is not described in detail herein, it may be assumed that the element is at least similar to a corresponding element that has been described in detail elsewhere within the present disclosure.

Some of the plurality of redistribution patterns arranged adjacent to the bottom surface of the primary conductive structure 510 may be referred to as the plurality of bottom surface connection pads 510B. Some of the plurality of redistribution patterns arranged adjacent to the top surface of the primary conductive structure 510 may be referred to as a plurality of primary top surface connection pads.

The plurality of connection vias 531 may be positioned on the plurality of primary top surface connection pads. The plurality of connection vias 531 may be electrically connected to a secondary top surface connection pad 542 to be described later, electrically connected to the conductive posts 410, and electrically connected to the plurality of redistribution patterns 120 of the lower redistribution structure 100.

The plurality of connection vias 531 may include copper (Cu) or a copper (Cu) alloy. The plurality of connection vias 531 may be made of the same kind of material as the conductive posts 410. Alternatively, the connection vias 531 may be made of the same material as the redistribution pattern or secondary vias 541A of the primary conductive structure. However, the material constituting the plurality of connection vias 531 is not necessarily limited thereto.

The upper encapsulant 520 may at least partially surround the plurality of connection vias 531 on the top surface of the primary conductive structure 510. The upper encapsulant 520 may fill a space between the primary conductive structure 510 and the secondary conductive structure 540. For example, the upper encapsulant 520 may have a thickness of about 20 μm to about 50 μm. For example, the upper encapsulant 520 may be a molding member including an epoxy mold compound (EMC).

The secondary conductive structure 540 includes an insulation layer, but unlike the lower redistribution structure 100 and the primary conductive structure 510, the secondary conductive structure 540 might not include a redistribution structure. The secondary vias 541A may be provided through the insulation layer constituting the secondary conductive structure 540. Each of the secondary vias 541A may be electrically connected to one end of each of the connection vias 531 located below the secondary vias 541A.

In some embodiments, the side surface of the primary conductive structure 510, the side surface of the upper encapsulant 520, and the side surface of the secondary conductive structure 540 may be aligned vertically with respect to each other to form a coplanar surface.

When the internal semiconductor device 300 is operating, heat may be generated. For operational stability of the internal semiconductor device 300, smooth heat dissipation of the internal semiconductor device 300 is provided. Since the internal semiconductor device 300 may contact the bottom surface of the primary conductive structure 510, heat generated from the internal semiconductor device 300 may be transferred to the primary conductive structure 510. Heat transferred to the primary conductive structure 510 may be transferred to secondary top surface connection pads 542 through the plurality of connection vias 531 located above the internal semiconductor device 300.

Heat generated during operations of the internal semiconductor device 300 may be transferred not only to the upper composite redistribution structure 500 but also to the lower encapsulant 430, the underfill layer 420, and the lower redistribution structure 100, which are in contact with the internal semiconductor device 300. The lower encapsulant 430, the underfill layer 420, and the lower redistribution structure 100 may have a lower heat transfer rate than the connection vias 531 and the secondary top surface connection pads 542, which are made of metal. Accordingly, heat generated from the internal semiconductor device 300 may be moved through the plurality of connection vias 531 to move to the secondary top surface connection pads 542 exposed to the outside of the semiconductor package 1. For example, heat generated from the internal semiconductor device 300 may be easily dissipated to the outside of the semiconductor package 1, which is one embodiment of the inventive concept.

In FIG. 2A, the plurality of connection vias 531 may be arranged in a shape (e.g., dotted line) in which the internal semiconductor device 300 overlaps the primary conductive structure 510 but the arrangement of the plurality of connection vias 531 is not necessarily limited by this drawing.

In FIG. 2B, two semiconductor devices may be horizontally spaced apart in the Y-axis direction. The plurality of connection vias 531 may be arranged in a shape (e.g., dotted line) in which the internal semiconductor device 300 overlaps the primary conductive structure 510. Likewise, in order to transfer heat generated from a rear surface semiconductor device located above in the drawing, the plurality of connection vias 531 may be arranged in a shape (e.g., dotted line) in which the rear surface semiconductor device is overlapped on the primary conductive structure 510. However, the arrangement of the plurality of connection vias 531 is not necessarily limited by the present drawing.

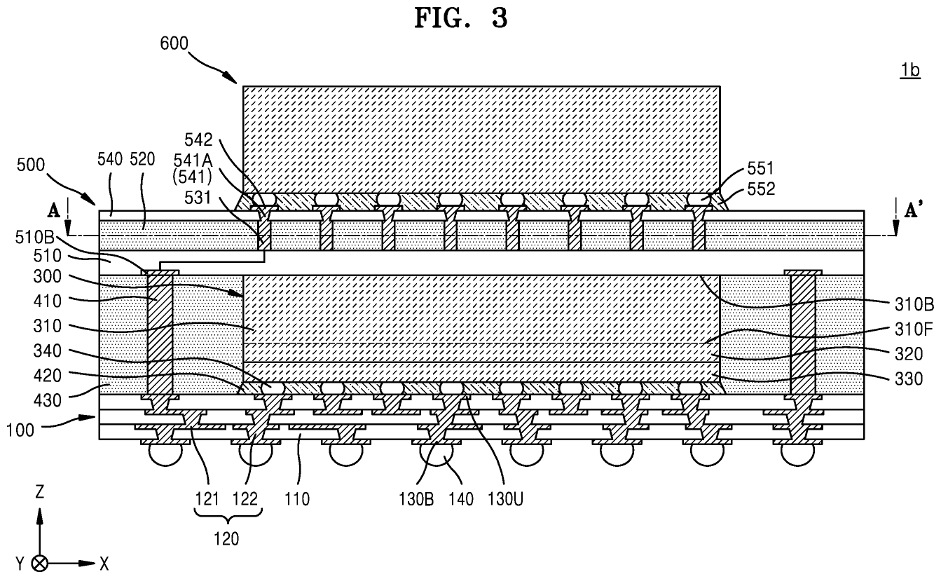

FIG. 3 is a cross-sectional view illustrating a semiconductor package 1b, according to an embodiment of the present disclosure. To the extent that an element is not described in detail herein, it may be assumed that the element is at least similar to a corresponding element that has been described in detail elsewhere within the present disclosure.

Referring to FIG. 3, an upper semiconductor device 600 may be mounted on secondary top surface connection pads 542. The upper semiconductor device 600 may be a semiconductor package including a semiconductor chip. Therefore, the semiconductor package 1b according to an embodiment of the inventive concept may have a package-on-package (PoP) structure.

A plurality of connection members 551 (e.g., connectors) may be located on a plurality of pads provided below the upper semiconductor device 600 and a plurality of secondary top surface connection pads 542 provided on the top surface of the upper composite redistribution structure 500. For example, each of the plurality of connection members 551 may be a solder ball or a micro bump. The plurality of connection vias 531 included in the upper composite redistribution structure 500 may be electrically connected to the upper semiconductor device 600 through a plurality of connection members 551. The plurality of connection members 551 may include, for example, copper (Cu), aluminum (Al), silver (Ag), tin (Tin), gold (Au), or solder, but are not necessarily limited thereto.

The semiconductor chip included in the upper semiconductor device 600 may be a semiconductor chip including a nonvolatile memory chip, such as flash memory, phase-change random access memory (PRAM), magnetoresistive random access memory (MRAM), ferroelectric random access memory (FeRAM), or resistive random access memory (RRAM). In some embodiments, the memory device may be a semiconductor chip including a volatile memory device, such as dynamic random access memory (DRAM) or static random access memory (SRAM).

The semiconductor chip included in the upper semiconductor device 600 may be a central processing device chip, a graphic processing device chip, or an application processor chip. In other embodiments, when the upper semiconductor device 600 includes a plurality of semiconductor chips, one of the plurality of semiconductor chips may be a central processing unit chip, a graphic processing unit chip, or an application processor chip, and the other may be a memory semiconductor chip including a memory device.

The upper semiconductor device 600 may be electrically connected to the connection vias 531 through the secondary top surface connection pads 542. Since the connection vias 531 are electrically connected to the conductive posts 410 and the lower redistribution structure 100, the upper semiconductor device 600 may be electrically connected to the internal semiconductor device 300. In addition, the upper semiconductor device 600 may exchange electrical signals with an external device through a plurality of external connection terminals 140.

The upper composite redistribution structure 500 included in the semiconductor package 1b, according to an embodiment of the inventive concept, includes the upper encapsulant 520 capable of relieving stress between the primary conductive structure 510 and the secondary conductive structure 540, and the connection vias 531 capable of increasing the coefficient of thermal expansion.

When the upper semiconductor device 600 is mounted on the upper composite redistribution structure 500, the thermal expansion coefficient of the upper semiconductor device 600 may be different from the thermal expansion coefficient of the lower semiconductor package, which is a part of the semiconductor package 1b except the upper semiconductor device 600. Since the coefficients of thermal expansion of the upper semiconductor device and the lower semiconductor package are different from each other, stress may occur in the semiconductor package during thermal expansion in the case of a semiconductor package having no upper composite redistribution structure 500. Due to the stress, reliability of the semiconductor package may be problematic.

The semiconductor package (1b), according to an embodiment of the inventive concept, may compensate for different thermal expansion coefficients of the upper semiconductor device 600 and the lower semiconductor package within a certain range by placing the upper composite redistribution structure 500 between the upper semiconductor device 600 and the lower semiconductor device 300.

In addition, the upper composite redistribution structure 500 includes the primary conductive structure 510, an intermediate area equipped with the upper encapsulant 520, and the connection vias 531, and the secondary conductive structure 540 to reduce stress caused by different thermal expansion coefficients of the upper semiconductor device 600 and the lower semiconductor package and buffer stress generated by the intermediate area. For example, due to the upper composite redistribution structure 500, reliability of the semiconductor package 1b may be increased.

As described above, heat generated from the internal semiconductor device 300 may move through the plurality of connection vias 531 to move to the secondary top surface connection pad 542 located outside the semiconductor package 1a. For example, heat generated from the internal semiconductor device 300 may be easily dissipated to the outside of the semiconductor package 1b, which is one embodiment of the inventive concept. For example, the semiconductor package 1b, according to an embodiment of the inventive concept, may better dissipate heat.

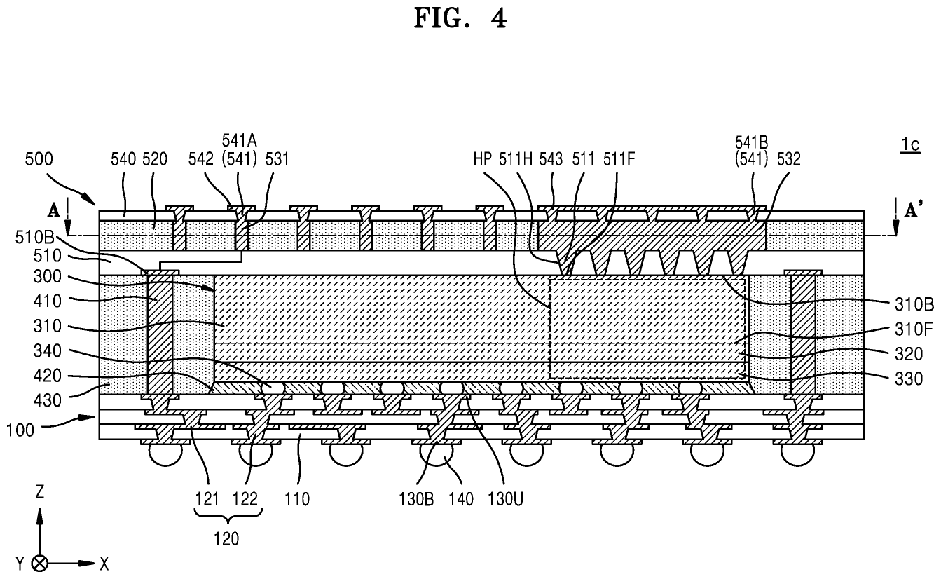

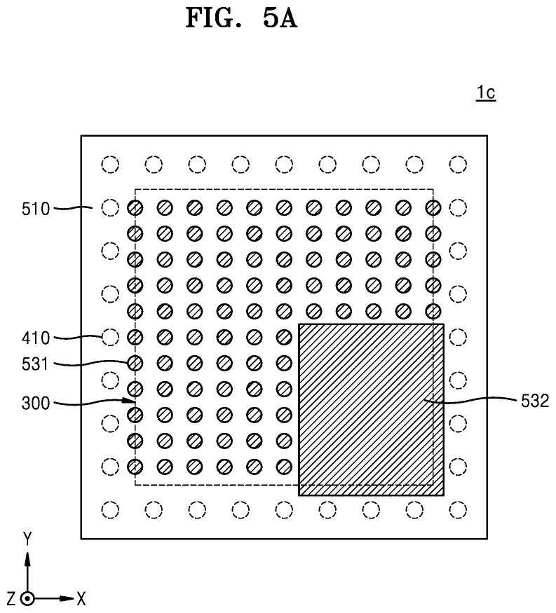

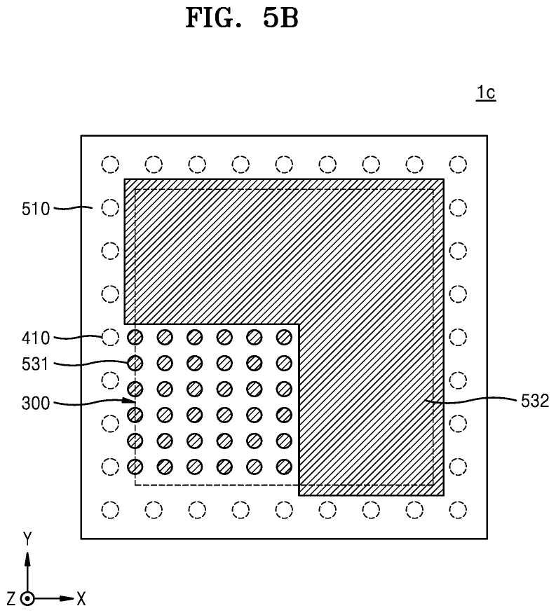

FIG. 4 is a cross-sectional view illustrating a semiconductor package 1c, according to an embodiment of the present disclosure. FIG. 5A is a plan view taken along a portion A-A′ of the semiconductor package 1c of FIG. 1, according to an embodiment of the present disclosure. To the extent that an element is not described in detail herein, it may be assumed that the element is at least similar to a corresponding element that has been described in detail elsewhere within the present disclosure.

Referring to FIGS. 4 and 5A, the upper composite redistribution structure 500 may further include first heat dissipation vias 511, a heat dissipation plate 532, second heat dissipation vias 541B, and a heat dissipation pad 543.

One or more via holes 511H may be provided in the primary conductive structure 510. The one or more via holes 511H may penetrate the primary conductive structure 510. The first heat dissipation vias 511 may be provided in each of the one or more via holes 511H. For example, the first heat dissipation vias 511 may be formed within each of the one or more holes 511H. A via bottom surface 511F is located at a lower end of the via hole 511H, and the top surface of the primary conductive structure 510 may form a coplanar surface together with the via bottom surface 511F. Each of the one or more via holes 511H may have a tapered shape in which a horizontal width decreases from a top surface to a bottom surface of the primary conductive structure 510. The via bottom surface 511F, which is the bottom surface of each of the first heat dissipation vias 511, may contact the inactive surface 310B, which is the top surface of the internal semiconductor device 300.

A heat dissipation plate 532 may be located between a top surface of the primary conductive structure 510 and a bottom surface of the secondary conductive structure 540. The heat dissipation plate 532 may be spaced apart from the plurality of connection vias 531 in the horizontal direction. The upper encapsulant 520 may at least partially surround a side surface of the heat dissipation plate 532. The top surface of the heat dissipation plate 532 may contact a portion of the bottom surface of the secondary conductive structure 540. The bottom surface of the heat dissipation plate 532 may contact a portion of the top surface of the primary conductive structure 510. The thickness of the heat dissipation plate 532 in the vertical direction may be equal to the distance between the primary conductive structure 510 and the secondary conductive structure 540 vertically spaced apart from each other. In an embodiment, the heat dissipation plate 532 may be made of a material such as the connection vias 531. The heat dissipation plate 532 may be formed in the same process as the connection vias 531.

A heat dissipation pad 543 may be positioned on the top surface of the secondary conductive structure 540. The heat dissipation pad 543 may be connected to the top surface of the heat dissipation plate 532 by second heat dissipation vias 541B. Unlike a case in which each of the plurality of secondary top surface connection pads 542 is individually arranged, the heat dissipation pad 543 may be integrally provided on the top surface of the secondary conductive structure 540.

In an embodiment, the heat dissipation pad 543 may be made of the same material as the plurality of secondary top surface connection pads 542. The heat dissipation pad 543 may be formed in the same process as the plurality of secondary top surface connection pads 542. The thickness of the heat dissipation pad 543 in the vertical direction may be the same as the thickness of each of the plurality of secondary top surface connection pads 542 in the vertical direction. In the present specification, the meaning that the numerical values are the same may be understood that the numerical values are in substantially the same range in consideration of process manufacturing errors.

In the semiconductor package 1c, according to an embodiment of the inventive concept, heat generated from the internal semiconductor device 300 may be easily dissipated to the outside of the semiconductor package 1c. Heat may be transferred from the inactive surface 310B, which is the top surface of the internal semiconductor device 300, to the heat dissipation plate 532 through the first heat dissipation vias 511. Heat may be transferred from the heat dissipation plate 532 to the heat dissipation pad 543 through the second heat dissipation vias 541B. For example, heat may be transferred from the internal semiconductor device 300 to the heat dissipation pad 543.

The first heat dissipation vias 511, the heat dissipation plate 532, the second heat dissipation vias 541B, and the heat dissipation pad 543 are made of metal, and may have a higher heat transfer rate than other components located around the internal semiconductor device 300. In addition, since the first heat dissipation vias 511 directly is in contact with the top surface of the internal semiconductor device 300, heat generation from the internal semiconductor device 300 may be more effectively dissipated. Accordingly, the semiconductor package 1c, according to an embodiment of the inventive concept, may better dissipate heat.

A hot spot HP may exist in a portion of the internal semiconductor device 300. The hot spot HP refers to a part of the internal semiconductor device 300 in which the temperature of heat generated from the internal semiconductor device 300 under the operation of the internal semiconductor device 300 is higher than those of other parts. In FIG. 4 and the following drawings, the hot spot HP of the virtual location is indicated by a rectangular dotted line, but the location of the hot spot HP is not necessarily limited thereto.

The first heat dissipation vias 511, the heat dissipation plate 532, the second heat dissipation vias 541B, and the heat dissipation pad 543 may be collectively referred to as heat dissipation parts below in the specification. The first heat dissipation vias 511, the heat dissipation plate 532, the second heat dissipation vias 541B, and the heat dissipation pad 543 constituting the heat dissipation part may include copper (Cu). In addition, the connection vias 531 may include copper (Cu). The heat dissipation part may be located in a portion of the upper composite redistribution structure 500, which is an upper part of a place where the spot HP is located.

In an embodiment, as shown in FIG. 4, the hot spot HP may be located on the right side of the internal semiconductor device 300 based on the drawing. As the distance between the hot spot HP and the heat dissipation part decreases, heat dissipation may be more effectively performed. For example, the heat dissipation part may be located above the hot spot HP, which is a part of the upper composite redistribution structure 500. In particular, a lot of heat may be generated in the hot spot HP which is a part of the internal semiconductor device 300, and the heat generated in the hot spot HP may be dissipated from the heat dissipation pad 543 through the first heat dissipation vias 511.

Accordingly, heat dissipation of the semiconductor package 1c, according to an embodiment of the inventive concept, may be smoothly performed by adjusting the position of the heat dissipation part according to the position of the hot spot HP. For example, the semiconductor package 1c, according to an embodiment of the inventive concept, may better dissipate heat due to the heat dissipation part.

As shown in FIG. 5A, a shape in which the heat dissipation plate 532 overlaps the primary conductive structure 510 may be rectangular. In an embodiment, the shape in which the heat dissipation plate 532 overlaps the primary conductive structure 510 may be rectangular. A shape in which the heat dissipation plate 532 overlaps the primary conductive structure 510 may be included within a boundary formed by the planar shape of the primary conductive structure 510.

Unlike FIGS. 2A and 2B, at least a part of the plurality of connection vias 531 may be arranged outside or across a boundary of a shape (e.g., dotted line) in which the internal semiconductor device 300 overlaps the primary conductive structure 510, but the arrangement of the plurality of connection vias 531 is not necessarily limited by these drawings.

FIG. 5B is a plan view taken along the portion A-A′ of the semiconductor package 1c, according to an embodiment of the present disclosure. To the extent that an element is not described in detail herein, it may be assumed that the element is at least similar to a corresponding element that has been described in detail elsewhere within the present disclosure.

Referring to FIG. 5B, a planar shape of the heat dissipation plate 532 may be L-shaped. In addition, the planar shape of the heat dissipation pad 543 may be L-shaped. The planar shape of the heat dissipation part including the heat dissipation plate 532 may have an ‘L-shape’, like the ‘L-shape’ that is the shape of the heat dissipation plate 532.

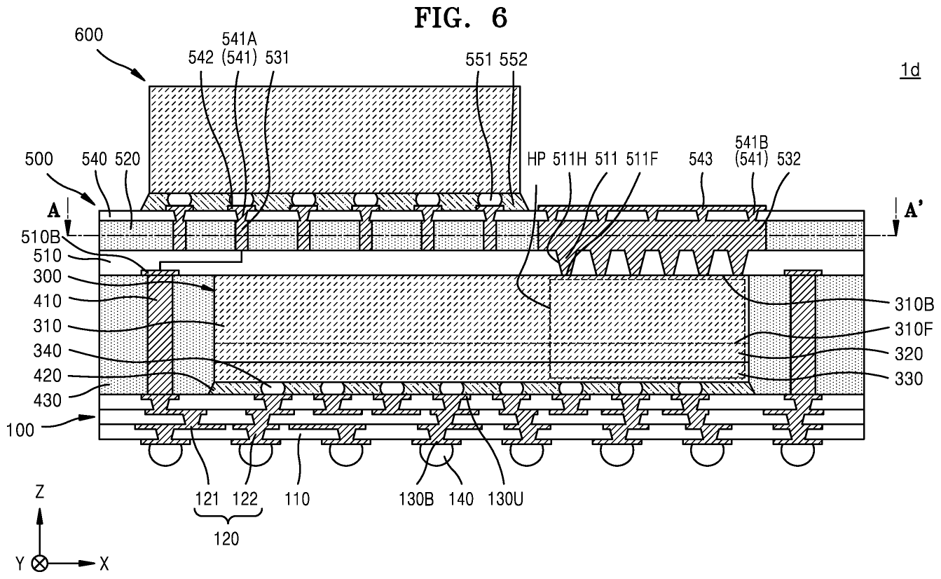

As shown in FIG. 6, an upper semiconductor device 600 may be mounted on the semiconductor package 1c, according to an embodiment of the inventive concept. A plurality of secondary top surface connection pads 542 connected to the connection vias 531 are arranged in a partial area of the top surface of the upper composite redistribution structure 500 on which the upper semiconductor device 600 is mounted. The heat dissipation pad 543 may be spaced apart from the plurality of secondary top surface connection pads 542. The upper semiconductor device 600 may be mounted on the upper composite redistribution structure 500, and an underfill layer 552 may be arranged between the upper semiconductor device 600 and the top surface of the upper composite redistribution structure 500.

For example, the secondary top surface connection pads 542 might not be provided in the region where the heat dissipation pad 543 is formed. Accordingly, the heat dissipation pad 543 might not be positioned in a partial area of the top surface of the upper composite redistribution structure 500 on which the upper semiconductor device 600 is mounted.

The heat dissipation pad 543 may be positioned except for a partial area of the top surface of the upper composite redistribution structure 500 on which the upper semiconductor device 600 is mounted. Accordingly, the shape of the heat dissipation plate 532 may be spaced apart from a plurality of connection vias 531 electrically connected to the upper semiconductor device 600.

As shown in FIG. 5B, a planar area of an area in which the plurality of connection vias 531 provided in the upper composite redistribution structure 500 are arranged may be less than a planar area of the heat dissipation plate 532.

In the semiconductor package 1c, according to an embodiment of the inventive concept, the shape of the heat dissipation part including the heat dissipation plate 532 may be determined according to the shape of the internal semiconductor device 300 of the semiconductor package 1c, the location of the hot spot HP that is a part of the internal semiconductor device 300, and the shape of the upper semiconductor device 600 mounted on the upper composite redistribution structure 500.

FIG. 6 is a cross-sectional view illustrating a semiconductor package 1d, according to an embodiment of the present disclosure. To the extent that an element is not described in detail herein, it may be assumed that the element is at least similar to a corresponding element that has been described in detail elsewhere within the present disclosure.

Referring to FIG. 6, an upper semiconductor device 600 may be mounted on secondary top surface connection pads 542. The upper semiconductor device 600 may be a semiconductor package including a semiconductor chip. Therefore, the semiconductor package 1d, according to an embodiment of the inventive concept, may have a package-on-package (PoP) structure.

The heat dissipation part may be positioned on a portion of the internal semiconductor device 300 in which the hot spot HP is located. The plurality of connection vias 531 may be positioned in the upper composite redistribution structure 500 in which the heat dissipation part is not positioned. The plurality of connection vias 531 may be electrically connected to the secondary top surface connection pads 542 positioned on the top surface of the upper composite redistribution structure 500. The upper semiconductor device 600 may be mounted on the secondary top surface connection pads 542.

Although the upper semiconductor device 600 is mounted on the upper composite redistribution structure 500, a heat dissipation pad 543 may be arranged on at least a portion of an area where the upper semiconductor device 600 is not covered with the upper composite redistribution structure 500 on the top surface of the upper composite redistribution structure 500. Accordingly, the semiconductor package 1d may better dissipate heat therethrough. In addition, the upper composite redistribution structure 500 may reduce the stress generated in the semiconductor package due to the difference in thermal expansion coefficient and buffer the stress. Accordingly, reliability of the semiconductor package 1c may be increased.

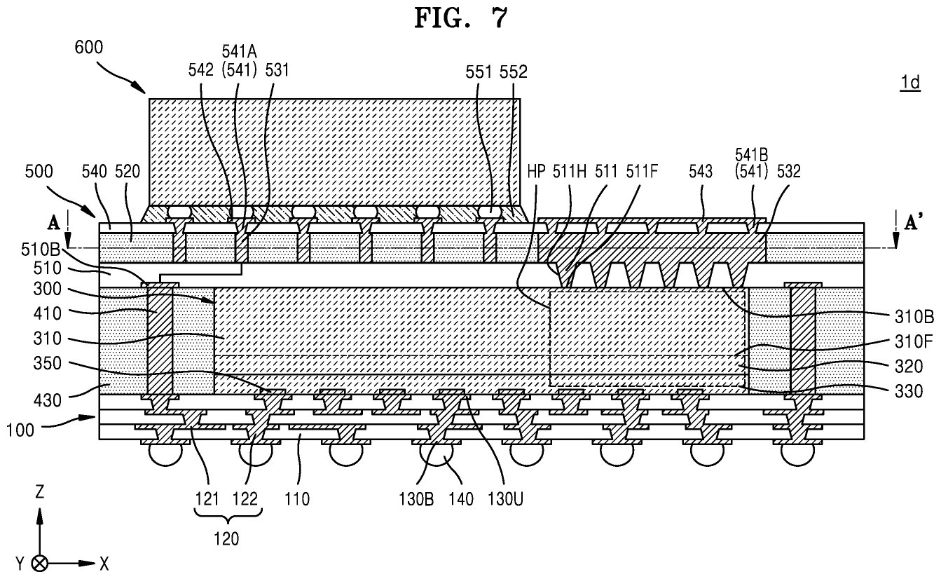

FIG. 7 is a cross-sectional view illustrating a semiconductor package 1e, according to an embodiment of the present disclosure. To the extent that an element is not described in detail herein, it may be assumed that the element is at least similar to a corresponding element that has been described in detail elsewhere within the present disclosure.

Referring to FIG. 7, the semiconductor package 1e, according to an embodiment of the inventive concept, may be a fan out panel level package (FOPLP). The lower redistribution structure 100 is formed on a bottom surface of the internal semiconductor device 300, and the plurality of connection pads 350 provided on a bottom surface of the internal semiconductor device 300 and the plurality of top surface connection pads 130U may be electrically connected to each other.

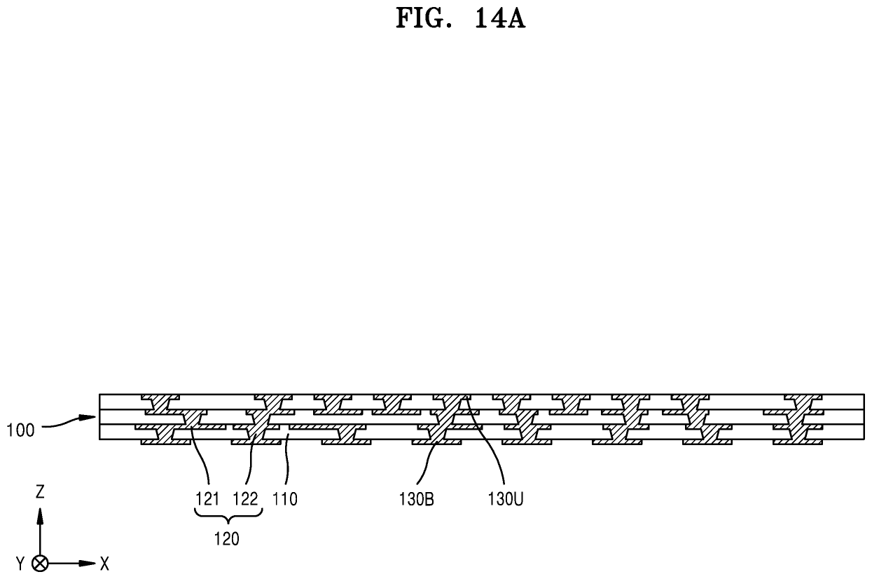

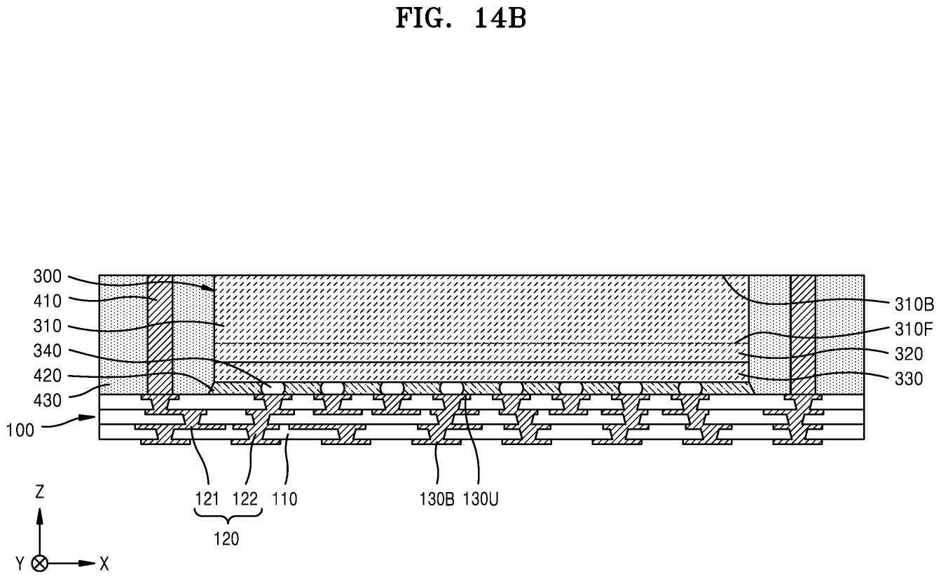

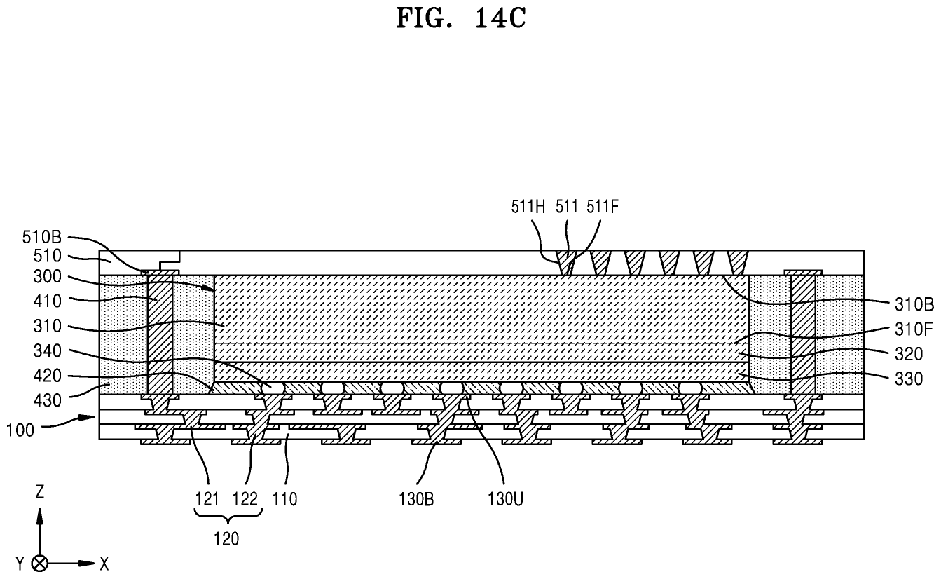

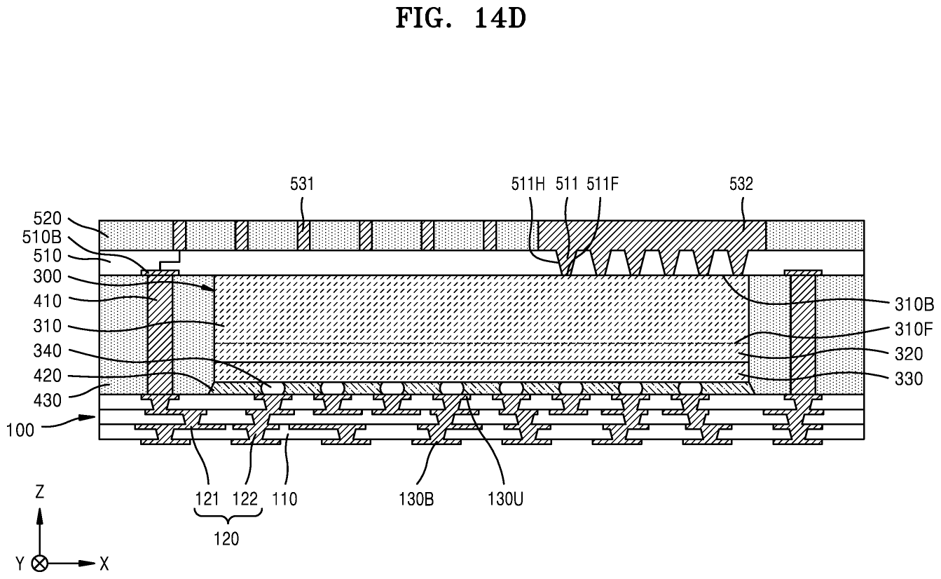

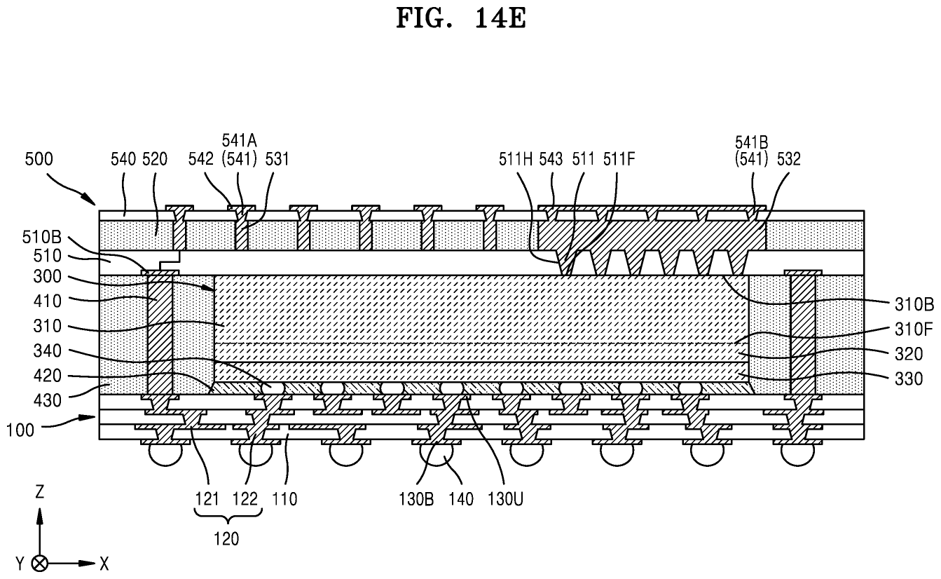

Unlike the order of the semiconductor package manufacturing process of FIGS. 14A to 14F to be described later, the semiconductor package 1e produced by FOPLP may have a different process order. After the upper composite redistribution structure 500 is formed first, the inactive surface 310B of the internal semiconductor device 300 is attached to the bottom surface of the upper composite redistribution structure 500 by an adhesive layer. Thereafter, the conductive posts 410 and the lower encapsulant 430 are formed, and the lower redistribution structure 100 is formed. The manufacturing process order of the upper composite redistribution structure 500 and the process of mounting the upper semiconductor device 600 are the same as the semiconductor package manufacturing process of FIGS. 14A to 14F to be described later.

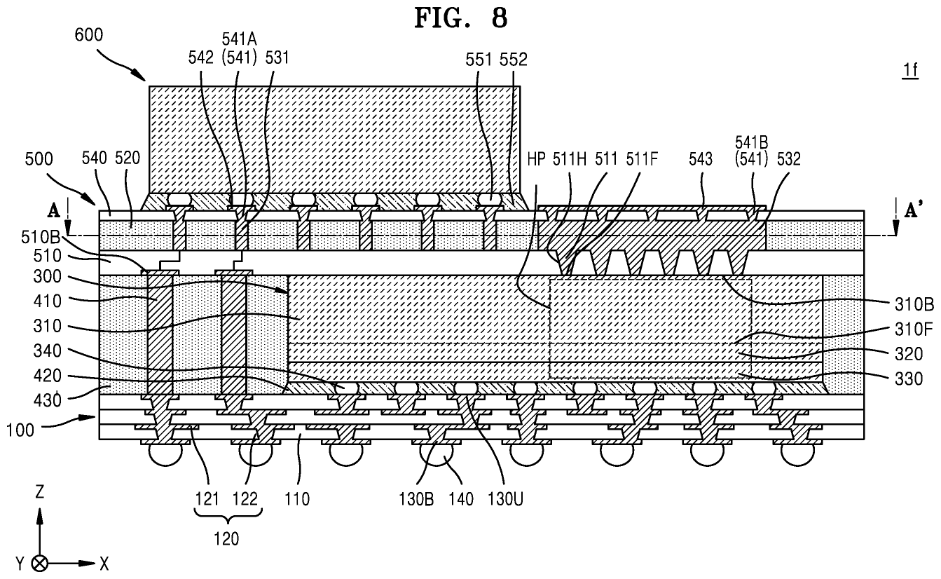

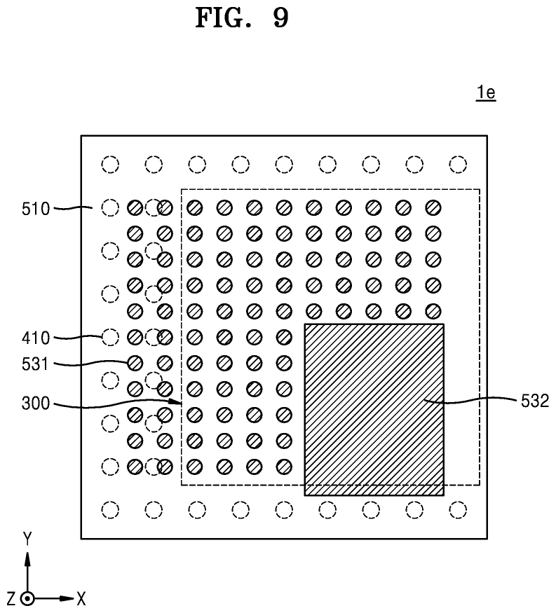

FIG. 8 is a cross-sectional view illustrating a semiconductor package if, according to an embodiment of the present disclosure. FIG. 9 is a plan view taken along a portion A-A′ of the semiconductor package if of FIG. 8, according to an embodiment of the present disclosure. To the extent that an element is not described in detail herein, it may be assumed that the element is at least similar to a corresponding element that has been described in detail elsewhere within the present disclosure.

Referring to FIGS. 8 and 9, the conductive posts 410 might not be located on one side surface of the side surfaces of the internal semiconductor device 300. Based on the side boundary of the lower redistribution structure 100 and the upper composite redistribution structure 500, the internal semiconductor device 300 may be biased to one side and arranged between the lower redistribution structure 100 and the upper composite redistribution structure 500. The upper semiconductor device 600 may transmit and receive an electrical signal via the conductive posts 410. Since the delay of the electrical signal may decrease as the position of the conductive post 410 is relatively close to the upper semiconductor device 600, the semiconductor package may be configured so that more conductive posts 410 are arranged at a place where the upper semiconductor device 600 is located. At the same time, a heat dissipation part consisting of the first heat dissipation vias 511, the heat dissipation plate 532, the second heat dissipation vias 541B, and the heat dissipation pad 543 may be located close to the hot spot HP.

The conductive post 410 may be positioned close to the upper semiconductor device 600 to reduce delay of the electrical signal of the upper semiconductor device 600, and the heat dissipation part may be positioned close to the hot spot HP of the internal semiconductor device 300 to better dissipate heat of the semiconductor package 1f. In addition, the upper composite redistribution structure 500 may reduce the stress generated in the semiconductor package due to the difference in thermal expansion coefficient and buffer the stress. Accordingly, reliability of the semiconductor package if may be increased.

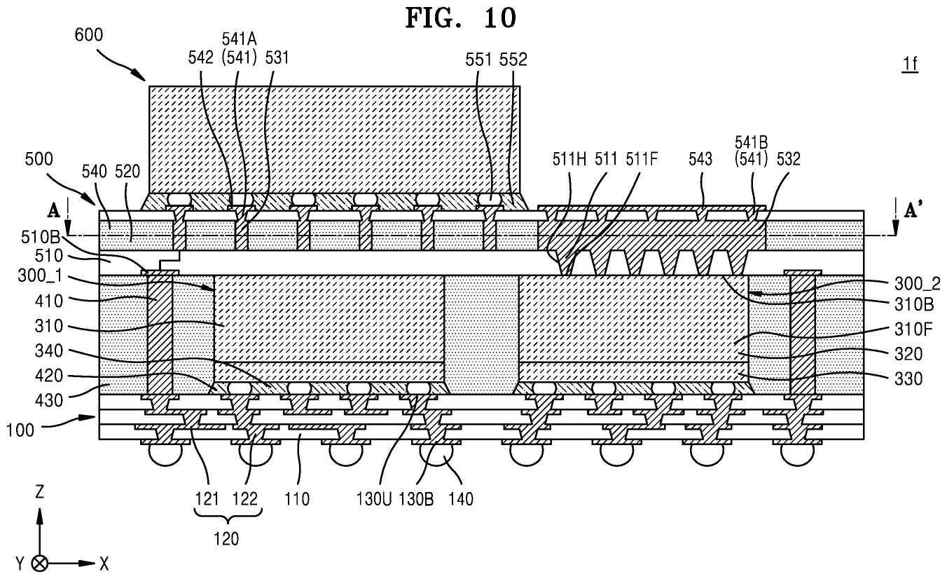

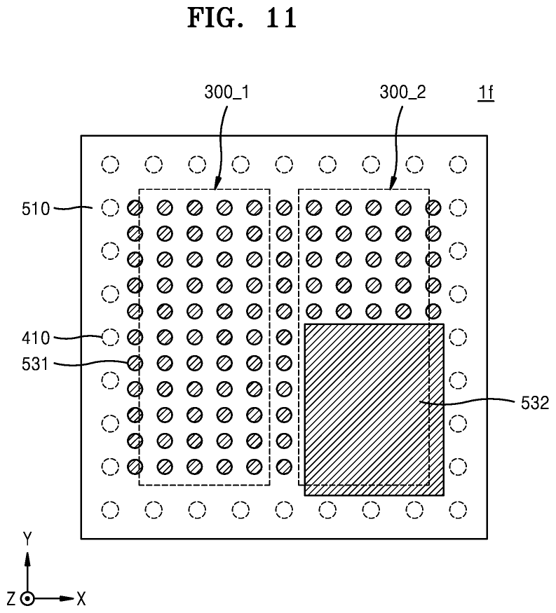

FIG. 10 is a cross-sectional view illustrating a semiconductor package 1f, according to an embodiment of the present disclosure. FIG. 11 is a plan view taken along the portion A-A′ of the semiconductor package 1 of FIG. 10, according to an embodiment of the present disclosure. To the extent that an element is not described in detail herein, it may be assumed that the element is at least similar to a corresponding element that has been described in detail elsewhere within the present disclosure.

A plurality of semiconductor devices may be arranged between the lower redistribution structure 100 and the upper composite redistribution structure 500. In an embodiment, as shown in FIG. 10, a first semiconductor device 300_1 and a second semiconductor device 3002 may be spaced apart from each other laterally and mounted on the lower redistribution structure 100.

For example, the first semiconductor device 3001 may generate less heat during operation than the second semiconductor device 300_2. Since the second semiconductor device 300_2 generates heat relatively greater than the first semiconductor device 300_1, a heat dissipation part including the first heat dissipation vias 511, the heat dissipation plate 532, the second heat dissipation vias 541B, and the heat dissipation pad 543 may be located above the second semiconductor device 300_2 in the upper composite redistribution structure 500. The first semiconductor device 300_1 that generates relatively less heat than the second semiconductor device 300_2 may be located below the upper composite redistribution structure 500 in which the connection vias 531 are located. Since the heat dissipation part is located in the second semiconductor device 300_2, which generates relatively more heat than the first semiconductor device 300_1, heat dissipation of the semiconductor package if may be effectively performed.

Through the semiconductor package if, according to an embodiment of the inventive concept, heat dissipation of the semiconductor package if may be increased by facilitating heat dissipation of the semiconductor device having relatively large heat generation. In addition, the upper composite redistribution structure 500 may reduce the stress generated in the semiconductor package due to the difference in thermal expansion coefficient and buffer the stress. Accordingly, reliability of the semiconductor package if may be increased.

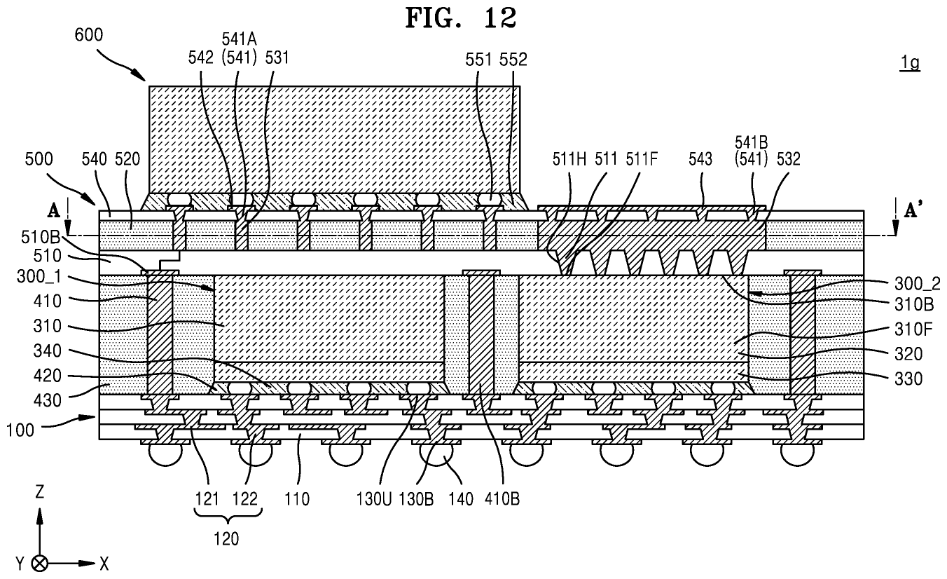

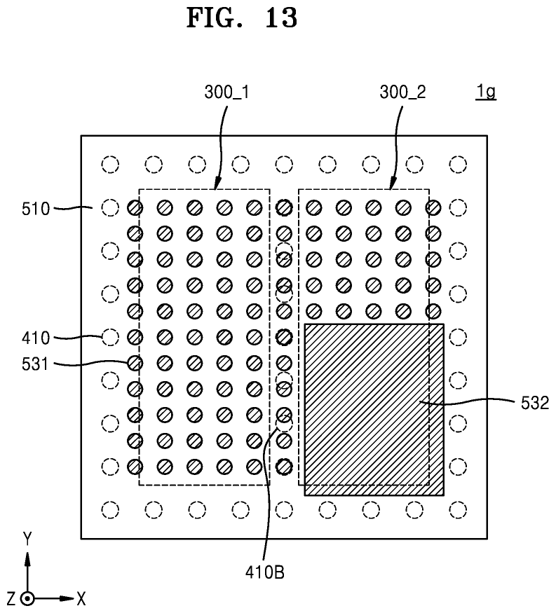

FIG. 12 is a cross-sectional view illustrating a semiconductor package 1g, according to an embodiment of the present disclosure. FIG. 13 is a plan view taken along the portion A-A′ of the semiconductor package 1g of FIG. 12, according to an embodiment of the present disclosure. To the extent that an element is not described in detail herein, it may be assumed that the element is at least similar to a corresponding element that has been described in detail elsewhere within the present disclosure.

As shown in FIGS. 10 and 11, in an embodiment, the first semiconductor device 300_1 that generates less heat than the second semiconductor device 3002 may be located below the upper composite redistribution structure 500 in which the connection vias 531 are located.

As shown in FIG. 12, a conductive post 410B may be further provided between the first semiconductor device 300_1 and the second semiconductor device 300_2 to be laterally spaced apart from the first semiconductor device 300_1 and the second semiconductor device 300_2. The upper semiconductor device 600 may transmit and receive an electrical signal via the conductive posts 410. As the positions of the conductive posts 410 are relatively close to the upper semiconductor device 600, the delay of the electrical signal may decrease. To be closer to the place where the upper semiconductor device 600 is located, the semiconductor package 1g may further include the conductive post 410B between the first semiconductor device 300_1 and the second semiconductor device 300_2.

The conductive post 410B may be positioned close to the upper semiconductor device 600 to reduce delay of the electrical signal of the upper semiconductor device 600, and the heat dissipation part may be positioned close to the hot spot HP of the internal semiconductor device 300 to increase heat dissipation of the semiconductor package 1g. In addition, the upper composite redistribution structure 500 may reduce the stress generated in the semiconductor package due to the difference in thermal expansion coefficient and buffer the stress. Accordingly, reliability of the semiconductor package 1g may be increased.

FIGS. 14A to 14E are cross-sectional views sequentially showing a process of manufacturing a semiconductor package 1c, according to an embodiment of the present disclosure.

Referring to FIG. 14A, a lower redistribution structure 100 is formed on a carrier substrate. The carrier substrate may include a second adhesive material layer such as a release film on one surface thereof. The lower redistribution structure 100 may include a plurality of redistribution insulation layers 110 sequentially stacked on the carrier substrate and a plurality of redistribution patterns 120 insulated by the plurality of redistribution insulation layers 110.

In order to form the lower redistribution structure 100, a first operation of forming a conductive material film on a carrier substrate and patterning the conductive material film to form a redistribution line pattern 121 of a first layer, a second operation of forming a redistribution insulation layer 110 covering the redistribution line pattern 121 of the first layer and having a via hole, and a third operation of forming a redistribution via pattern 122 filling the via hole of the redistribution insulation layer 110, and a redistribution line pattern 121 extending along the top surface of the redistribution insulation layer 110 may be performed, and then the second and third operations may be repeatedly performed several times.

Referring to FIG. 14B, a plurality of top surface connection pads 130U to be connected to conductive posts 410 and a plurality of chip connection members 340 to be described later may be patterned and formed. The conductive posts 410 may be formed on the plurality of top surface connection pads 130U positioned on the lower redistribution structure 100.

A connection pad located on the bottom surface of the internal semiconductor device 300 and a plurality of top surface connection pads 130U formed on the top surface of the lower redistribution structure 100 are electrically connected through a plurality of chip connection members 340. For example, the internal semiconductor device 300 may be mounted on the top surface of the lower redistribution structure 100. For example, chip connection members 340 such as micro bumps are located on the bottom surface of the internal semiconductor device 300, so that the internal semiconductor device 300 may be mounted on the lower redistribution structure 100 in a flip chip manner.

The underfill layer 420 may surround the plurality of chip connection members 340 between a bottom surface of the internal semiconductor device 300 and a top surface of the lower redistribution structure 100. For example, the underfill layer 420 may be made of a resin material formed by a capillary underfill method.

A lower encapsulant 430 may surround semiconductor devices located on the lower redistribution structure 100. The lower encapsulant 430 may be formed on the lower redistribution structure 100 to surround the internal semiconductor device 300 and the conductive posts 410. For example, the lower encapsulant 430 may be formed through a molded underfill process.

Thereafter, a polishing process is performed on the result of forming the lower encapsulant 430 until the conductive posts 410 are exposed. A part of the lower encapsulant 430 and a part of each of the conductive posts 410 may be removed by the polishing process. As a result of performing the polishing process, the top surface of the lower encapsulant 430 and the surfaces of the conductive posts 410 may be exposed. In an embodiment, polishing may be performed so that the top surface of the internal semiconductor device 300 is exposed. The top surface of the lower encapsulant 430, the exposed cross section of each of the conductive posts 410, and the top surface of the internal semiconductor device 300 may be coplanar. For example, the polishing process may include a grinding process using a diamond wheel, etch-back, chemical mechanical polishing, etc.

Referring to FIG. 14C, after forming connection pads contacting an upper portion of each of the conductive posts 410, a process for forming a redistribution structure such as the lower redistribution structure 100 may be performed. The process for forming the redistribution structure is the same as described above, and thus will be omitted.

In the process of forming the redistribution via pattern during the process of forming the primary conductive structure 510, a first heat dissipation vias 511 provided in each of via holes 511H may be formed by overlapping the redistribution via pattern at the same location as shown in FIG. 14C. Accordingly, the material forming the first heat dissipation vias 511 may include the same material as the material forming the redistribution pattern of the primary conductive structure 510.

Referring to FIG. 14D, connection vias 531 are formed on the primary conductive structure 510 and a heat dissipation plate 532 is formed on a plurality of first heat dissipation vias 511.

In an embodiment, a photo resist (PR) pattern may be formed through a photo process. After a cleaning process for the formed PR pattern, the plurality of connection vias 531 and the heat dissipation plate 532 may be formed through electroplating.

After forming the plurality of connection vias 531 and the heat dissipation plate 532, the PR pattern may be removed through a strip/ashing process. An upper encapsulant 520 surrounding the connection posts and the side surfaces of the heat dissipation plate 532 may be formed on the primary conductive structure 510. Thereafter, the polishing process as described above may be performed. By the polishing process, the upper portions of the upper encapsulant 520, the plurality of connection vias 531, and the heat dissipation plate 532 may be partially removed. As a result of the polishing process, the top surface of the upper encapsulant 520, the top surfaces of the plurality of connection vias 531, and the top surface of the heat dissipation plate 532 may be coplanar.

Referring to FIG. 14E, a secondary conductive structure 540 may be formed on a top surface of the upper encapsulant 520. A redistribution structure might not be provided in the secondary conductive structure 540. However, the secondary conductive structure 540 may be provided with vias 541. At least some of the vias 541 may be secondary vias 541A in which the secondary top surface connection pads 542 are formed on the top surfaces thereof. The remaining vias 541 may be second heat dissipation vias 541B connected to the bottom surface of a heat dissipation pad 543.

After the secondary conductive structure 540 and the vias 541 are formed, the secondary top surface connection pads 542 and the heat dissipation pad 543 may be formed through a photo process and patterning. Thereafter, external connection terminals 140 may be formed on a plurality of bottom surface connection pads 130B, respectively.

While the inventive concept has been particularly shown and described with reference to embodiments thereof, it will be understood that various changes in form and details may be made therein without departing from the spirit and scope of the present disclosure.

What is claimed is:

1. A semiconductor package, comprising:
a lower redistribution structure;
a semiconductor device disposed on the lower redistribution structure;
a lower encapsulant disposed on the lower redistribution structure and surrounding a side surface of the semiconductor device; and
an upper composite redistribution structure disposed on an upper portion of the semiconductor device,
wherein the upper composite redistribution structure includes:
a primary conductive structure;
a secondary conductive structure disposed on the primary conductive structure;
connection vias disposed between the primary conductive structure and the secondary conductive structure; and
an upper encapsulant disposed between the primary conductive structure and the secondary conductive structure and surrounding the connection vias.

2. The semiconductor package of claim 1, further comprising a connection pad electrically connected to each of the connection vias and disposed on the secondary conductive structure, wherein the primary conductive structure includes a redistribution structure.

3. The semiconductor package of claim 2, wherein the secondary conductive structure does not include a redistribution structure.

4. The semiconductor package of claim 3, wherein side surfaces of the primary conductive structure, the secondary conductive structure, and the upper encapsulant are aligned with one another to form a coplanar surface.

5. The semiconductor package of claim 3, wherein
the semiconductor device includes a logic device, and
the semiconductor package further comprises an upper semiconductor device electrically connected to the connection pads, mounted on the upper composite redistribution structure, and including a memory device.

6. The semiconductor package of claim 3, further comprising
a heat dissipation plate disposed between the primary conductive structure and the secondary conductive structure,
wherein first heat dissipation vias passing through the primary conductive structure are disposed in the primary conductive structure, and
wherein one end of each of the first heat dissipation vias is in contact with a top surface of the semiconductor device, and the other end of each of the first heat dissipation vias is connected to a bottom surface of the heat dissipation plate.

7. The semiconductor package of claim 6, wherein a thickness of the upper encapsulant in a vertical direction is equal to a thickness of the heat dissipation plate in the vertical direction.

8. The semiconductor package of claim 6, wherein the heat dissipation plate is spaced apart from the connection vias and a side surface of the heat dissipation plate is surrounded by the upper encapsulant.

9. The semiconductor package of claim 6, wherein the heat dissipation plate comprises a same material as the connection vias.

10. The semiconductor package of claim 8, wherein a part of the semiconductor device is a hot spot that generates relatively high heat as compared to other parts thereof when the semiconductor device is operating, and the heat dissipation plate and the first heat dissipation vias are arranged on a vertical upper portion of the hot spot.

11. The semiconductor package of claim 8, wherein
second heat dissipation vias passing through the secondary conductive structure are disposed in the secondary conductive structure, and
one end of each of the second heat dissipation vias is in contact with the heat dissipation plate.

12. The semiconductor package of claim 11, wherein each of the second heat dissipation vias has a tapered shape in which a width of each of the second heat dissipation vias in a horizontal direction increases farther away from the heat dissipation plate.

13. The semiconductor package of claim 11, further comprising a heat dissipation pad disposed on the secondary conductive structure and having a bottom surface connected to the other end of each of the second heat dissipation vias.

14. The semiconductor package of claim 13, wherein
a thickness of each of the connection pads in a vertical direction is equal to a thickness of the heat dissipation pad in the vertical direction, and
the heat dissipation pad comprises a same material as the connection pads.

15. The semiconductor package of claim 13, wherein the connection vias, the first heat dissipation vias, the heat dissipation plate, the second heat dissipation vias, and the heat dissipation pad comprise copper (Cu).

16. A semiconductor package, comprising:
a lower redistribution structure;
a semiconductor device disposed on the lower redistribution structure;
a lower encapsulant disposed on the lower redistribution structure and surrounding a side surface of the semiconductor device;
an upper composite redistribution structure disposed on an upper portion of the semiconductor device; and
conductive posts electrically connecting the upper composite redistribution structure with the lower redistribution structure and spaced apart from the semiconductor device,
wherein the upper composite redistribution structure includes:
a first conductive structure;
a second conductive structure disposed on an upper portion of the first conductive structure;
connection vias disposed between the first conductive structure and the second conductive structure;
an upper encapsulant disposed between the primary conductive structure and the secondary conductive structure and surrounding a side surface of the connection vias; and
a connection pad electrically connected to each of the connection vias and disposed on the second conductive structure.

17. The semiconductor package of claim 16, further comprising:
first heat dissipation vias passing through the primary conductive structure and having one end thereof contacting a top surface of the semiconductor device;
a heat dissipation plate disposed between the primary conductive structure and the secondary conductive structure and connected to the other end of each of the first heat dissipation vias;
second heat dissipation vias passing through the secondary conductive structure and having one end contacting the heat dissipation plate; and
a heat dissipation pad disposed on the secondary conductive structure and having a bottom surface contacting the other end of each of the second heat dissipation vias.

18. The semiconductor package of claim 16, wherein the semiconductor device comprises two or more semiconductor devices laterally spaced apart from each other.

19. The semiconductor package of claim 17, wherein
the semiconductor device includes a logic device, and
the semiconductor package further comprises an upper semiconductor device disposed on the upper composite redistribution structure, electrically connected to the connection pads, and including a memory device.

20. A semiconductor package, comprising:
a lower redistribution structure;
a semiconductor device disposed on the lower redistribution structure and including a logic device;
a lower encapsulant disposed on the lower redistribution structure and surrounding a side surface of the semiconductor device;
an upper composite redistribution structure disposed on the semiconductor device;
conductive posts electrically connecting the upper composite redistribution structure with the lower redistribution structure and spaced apart from the semiconductor device; and
an upper semiconductor device disposed on the upper composite redistribution structure and including a memory device,
wherein the upper composite redistribution structure comprises:
a primary conductive structure;
a secondary conductive structure disposed on an upper portion of the primary conductive structure;
connection vias disposed between the primary conductive structure and the secondary conductive structure;
a heat dissipation plate disposed between the primary conductive structure and the secondary conductive structure and laterally spaced apart from the connection vias;
an upper encapsulant disposed between the primary conductive structure and the secondary conductive structure and surrounding the connection vias and a side surface of the heat dissipation plate;
first heat dissipation vias passing through the primary conductive structure, and having one end contacting a top surface of the semiconductor device and the other end contacting the heat dissipation plate;
second heat dissipation vias passing through the secondary conductive structure and having one end contacting the heat dissipation plate;
a connection pad electrically connected to each of the connection vias and disposed on the secondary conductive structure; and
a heat dissipation pad disposed on the secondary conductive structure and having a bottom surface contacting the other end of each of the second heat dissipation vias.
